(19) United States
(12) Patent Application Publication
(10) Pub. No.: US 2024/0419199 A1
(43) Pub. Date: Dec. 19, 2024

(54) PROCESSING EQUIPMENT AND CONTROL METHOD THEREOF

(71) Applicant: LAPLACE Renewable Energy Technology Co., Ltd., Shenzhen (CN)

(72) Inventors: Yang Li, Shenzhen (CN); Wenlong Mao, Shenzhen (CN); Tairong Zhu, Shenzhen (CN); Xiao Liang, Shenzhen (CN)

(21) Appl. No.: 18/757,594

(22) Filed: Jun. 28, 2024

(30) Foreign Application Priority Data
Jun. 6, 2024 (CN) 202410735785.0

(51) Int. Cl. G05D 23/19; F27B 17/00; F27D 19/00; F27D 21/00; H01L 21/67; H05B 1/02

(52) U.S. Cl. CPC G05D 23/1902; F27B 17/0016; F27D 19/00; H05B 1/0233; F27D 2019/0018; F27D 21/0014; H01L 21/67109; H01L 21/67248; H05B 2203/005

(57) ABSTRACT

A processing equipment and a control method thereof are provided. The processing equipment includes a furnace body, a temperature sensor, and a heater unit. A furnace cavity of the furnace body divided into main heating zones and auxiliary heating zones. The heater unit includes main heating elements located in the main heating zones and auxiliary heating elements located in the auxiliary heating zones. The control method includes obtaining an actual temperature detected by the temperature sensor; determining a first heating power according to a first temperature difference and a first preset adjustment rule; determining a second heating power according to the first heating power and a preset adjustment parameter; adjusting an actual working power of the main heating elements to the first heating power, adjusting an actual working power of the auxiliary heating elements to the second heating power.

### CROSS-REFERENCE TO RELATED APPLICATIONS

This application claims priority to Chinese Patent Application No. 202410735785.0 filed on Jun. 6, 2024 in China State Intellectual Property Administration, the contents of which are incorporated by reference herein.

### TECHNICAL FIELD

The present disclosure relates to the field of photovoltaic materials or semiconductor materials processing technologies, in particular to a processing equipment and a control method of the processing equipment.

### BACKGROUND

Furnace equipment is often used to process photovoltaic or semiconductor products. Furnace equipment usually tries to be as uniform as possible in terms of furnace wire winding, layout, pitch, etc., so as to make the temperature field in the furnace as uniform as possible, thereby ensuring the quality of the finished product. However, during the production process, due to the asymmetric layout of the products in the furnace, the difference in distance between different parts and the furnace wire, the uneven thermal resistance of different parts, etc., after the furnace wire is heated, the temperature of different parts of the product is likely to be different, thereby reducing the uniformity of the temperature field distribution in the furnace.

### BRIEF DESCRIPTION OF THE DRAWINGS

FIG. 1 is a schematic structural diagram of a processing equipment of a first embodiment and a second embodiment of the present disclosure.

FIG. 2 is a perspective schematic diagram of a furnace body and a furnace tube of the processing equipment of FIG. 1.

FIG. 3 is a cross-sectional view of the furnace body and the furnace tube of the processing equipment of FIG. 1.

FIG. 4 is a side view of the furnace body and the furnace tube of the first embodiment of the present disclosure.

FIG. 5 is a schematic diagram of a connection of a temperature sensor, a control unit, and a heater unit of the first embodiment of the present disclosure.

FIG. 6 is a flowchart of a control method of the processing equipment of the first embodiment of the present disclosure.

FIG. 7 is a schematic diagram of a first predetermined adjustment rule of the first embodiment of the present disclosure.

FIG. 8 is a side view of the furnace body and the furnace tube of the second embodiment of the present disclosure.

FIG. 9 is a schematic diagram of a connection of the temperature sensor, the control unit, and the heater unit of the second embodiment of the present disclosure.

FIG. 10 is a flowchart of the control method of the processing equipment of the second embodiment of the present disclosure.

### DETAILED DESCRIPTION

In order to make the purpose, technical solutions and advantages of the embodiments of the present disclosure clearer, the technical solutions in the embodiments of the present disclosure will be described clearly and completely in conjunction with the drawings in the embodiments of the present disclosure. Based on the embodiments of the present disclosure, all other embodiments obtained by those of ordinary skill in the art without creative work shall fall within the scope of protection of the present disclosure.

Those skilled in the art should understand that, in the disclosure of the present disclosure, “at least one” refers to one or more, and multiple refers to two or more. Unless otherwise defined, all technical and scientific terms used herein have the same meaning as commonly understood by those skilled in the technical field in the present disclosure. The terminology used in the specification of present disclosure is only for the purpose of describing specific embodiments, and is not intended to limit the present disclosure.

It can be understood that, unless otherwise specified in the present disclosure, “/” means “or”. For example, A/B can mean A or B. “A and/or B” in the present disclosure is only an associative relationship describing the associated objects, which means that there can be three relationships: only A, only B, and A and B.

It can be understood that, in the disclosure of the present disclosure, the words such as “first” and “second” are only used for the purpose of distinguishing description, and cannot be understood as indicating or implying relative importance, nor as indicating or implying any order. The features defined with “first” and “second” may explicitly or implicitly include one or more of the features. In the description of the embodiments of the present disclosure, the words such as “exemplary” or “for example” are used as examples, illustrations, or indications. Any embodiment or design solution described as “exemplary” or “for example” in the embodiments of the present disclosure should not be construed as being more preferable or advantageous than other embodiments or design solutions. To be precise, the words such as “exemplary” or “for example” are used to present related concepts in a specific manner.

Those skilled in the art should understand that, in the disclosure of the present disclosure, the terms “longitudinal”, “lateral”, “upper”, “lower”, “front”, “rear”, “left”, “right”, the orientation or positional relationship indicated by “vertical”, “horizontal”, “top”, “bottom”, “inner”, “outer”, etc. are based on the orientation or positional relationship shown in the drawings, which is only for the convenience of describing the present disclosure and to simplify the description, rather than indicating or implying that the device or element referred to must have a specific orientation, or be constructed and operated in a specific orientation, so the above terms should not be understood as limiting the present disclosure.

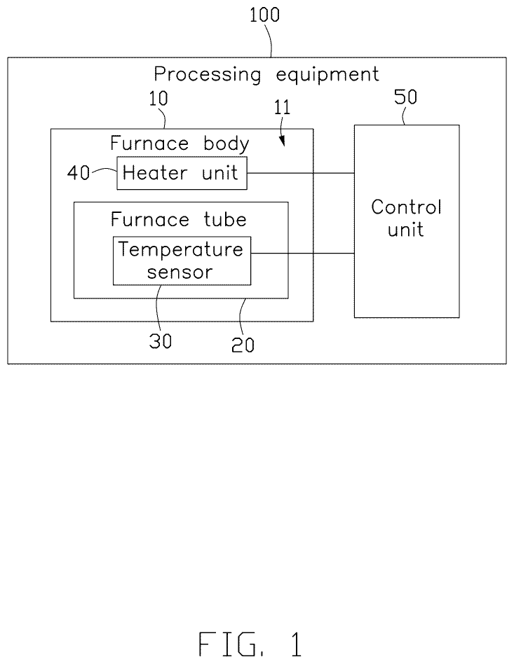

FIG. 1 illustrates a processing equipment 100 provided by embodiments of the present disclosure.

The processing equipment 100 can be a diffusion furnace or other types of furnaces used in a processing and manufacturing process of photovoltaic cells, such as a sintering furnace, a low-temperature furnace, a LPCVD reacting furnace, a PECVD reacting furnace, an oxidation furnace, a boron diffusion furnace, etc., which will not be limited here.

Referring to FIG. 1, the processing equipment 100 includes a furnace body 10, a furnace tube 20, a temperature sensor 30, a heater unit 40, and a control unit 50. The furnace body 10 is sleeved outside the furnace tube 20, and there is a certain distance between the furnace body 10 and the furnace tube 20. Shapes of the furnace body 10 and the furnace tube 20 can be set according to actual needs. For the convenience of description, FIG. 1 takes the furnace body 10 and the furnace tube 20 as an example in which both are cylindrical. At least a part of the temperature sensor 30 is arranged in the furnace body 10. The heater unit 40 is arranged in the furnace body 10. The control unit 50 is arranged outside the furnace body 10, the control unit 50 is connected to the temperature sensor 30 and the heater unit 40. In some embodiments, the heater unit 40 can be arranged between the furnace body 10 and the furnace tube 20; or the heater unit 40 can also be arranged in the furnace tube 20.

In actual use, the furnace tube 20 can be used to receive sheet materials to be processed (not shown in FIG. 1), the sheet materials are placed in the furnace tube 20 vertically. The sheet materials include, but are not limited to, semiconductor sheet materials and photovoltaic sheet materials, such as silicon wafers, ceramic substrates, battery cells, and the like. The heater unit 40 is used to generate heat when powered on to perform heat treatment on the sheet materials. Under certain temperature and pressure conditions, the sheet materials can react chemically with process gas in the furnace tube 20 to form a process layer (e.g., a thin film layer formed by chemical vapor deposition). The temperature sensor 30 can be used to feedback an actual temperature in the furnace body 10. The control unit 50 can be used to control the operation of the heater unit 40, thereby adjusting the actual temperature in the furnace body 10, so that the temperature in the furnace body 10 is evenly distributed, thereby helping to ensure that the process layer meets process requirements.

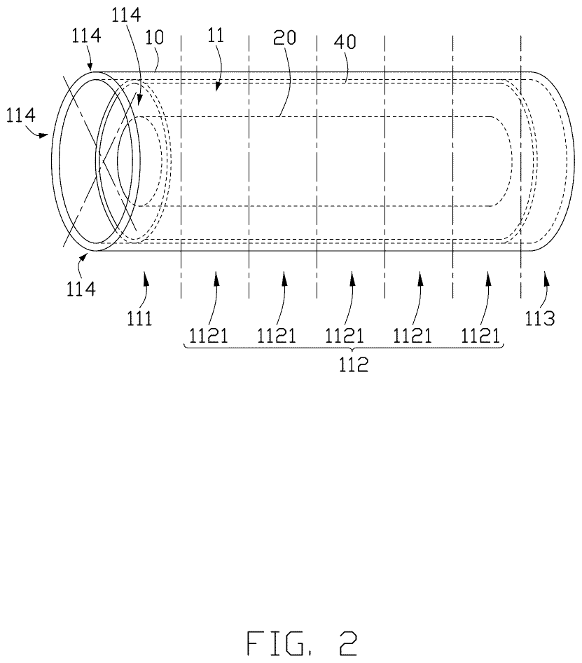

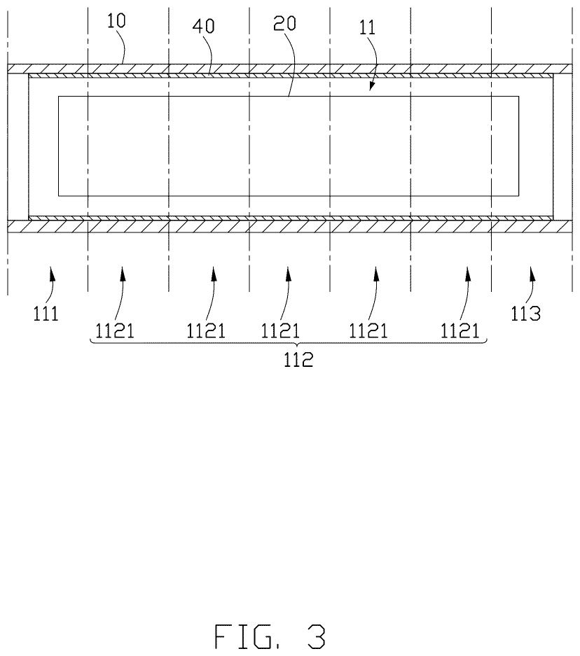

Furthermore, referring to FIGS. 2 and 3, a furnace chamber 11 of the furnace body 10 can be divided into a furnace front auxiliary heating zone 111, a process zone 112, and a furnace rear auxiliary heating zone 113 in sequence along a length direction of the furnace body 10. The furnace front auxiliary heating zone 111 is close to a furnace front (or named as furnace opening or furnace mouth) of the furnace body 10, and the furnace rear auxiliary heating zone 113 is close to a rear end (or named as furnace tail) of the furnace body 10. The process zone 112 can be further divided into a plurality of temperature zones 1121 along the length direction of the furnace body 10. In actual use, the sheet materials are placed in the temperature zone 1121.

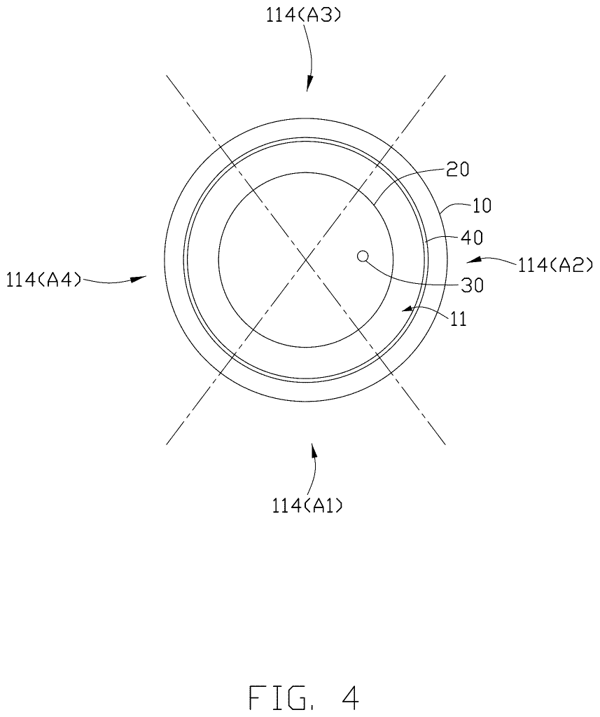

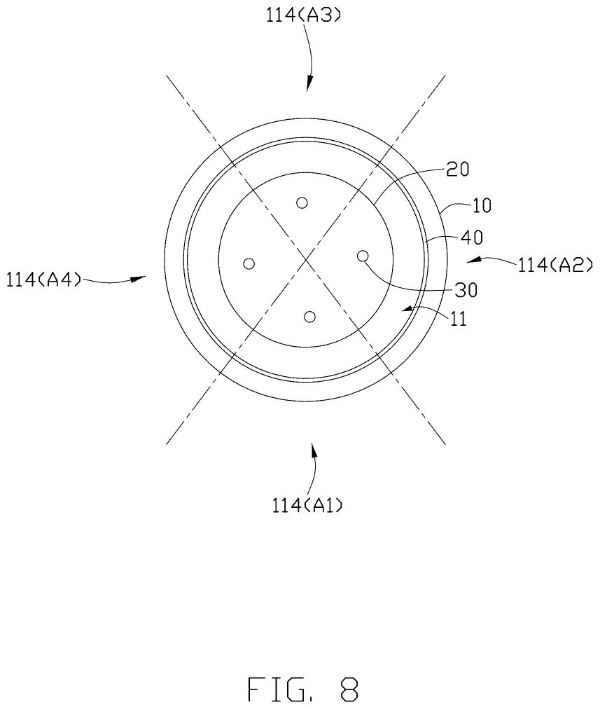

The furnace cavity 11 of the furnace body 10 can be divided into K partitions 114 along a circumference of the furnace body 10, and the K partitions 114 are distributed along the circumference of the furnace body 10. N partitions 114 located in a first direction serve as N main heating zones 1141, and M partitions 114 located in a second direction serve as M auxiliary heating zones 1142, N+M=K, K is an even number not less than 4, and N and M are both positive integers not less than 2. An angle between the first direction and a height direction of the furnace body 10 is a right angle or an obtuse angle, and an angle between the second direction and the height direction of the furnace body 10 is 0 or an acute angle. For example, when K=4 and N=M=2, as shown in FIG. 4 and FIG. 8, the furnace cavity 11 of the furnace body 10 is divided into partitions A1-A4 along the circumference direction of the furnace body 10. Partitions A1 and A2 are located in the first direction perpendicular to the height direction of the furnace body 10 (where A1 is a left partition and A2 is a right partition), so partitions A1 and A2 are both main heating zones 1141. Partitions A3 and A4 are located in the second direction that coincides with the height direction of the furnace body 10 (where A3 is an upper partition and A4 is a lower partition), so partitions A3 and A4 are both auxiliary heating zones 1142.

Accordingly, the heater unit 40 includes N main heating elements 41 and M auxiliary heating elements 42, the main heating elements 41 correspond to the main heating zones 1141 one by one, and each main heating element 41 is located in the corresponding main heating zone 1141. The auxiliary heating elements 42 correspond to the auxiliary heating zones 1142 one by one, and each auxiliary heating element 42 is located in the corresponding auxiliary heating zone 1142. The main heating elements 41 and the auxiliary heating elements 42 can be any element that can generate heat through electricity, such as electric furnace wire, graphite electrode, etc., which is not limited here.

The control unit 50 can be used to execute the control method of the processing equipment 100 provided in the embodiments of the present disclosure to control the operation of the main heating elements 41 and the auxiliary heating elements 42 to achieve precise temperature adjustment of the main heating zones 1141 and the auxiliary heating zones 1142. The control unit 50 may be any circuit having control and operation processing functions. The control unit 50 may be integrated and execute all steps of the control method. The control unit 50 may also be split into two or more controllers, each of which executes different parts or steps in the control method to jointly complete the entire control method.

Since the main heating zones 1141 and the auxiliary heating zones 1142 are distributed along the circumference direction of the furnace body 10, different parts of the sheet materials can be located in different main heating zones 1141 or auxiliary heating zones 1142. When adjusting the temperatures of the main heating zones 1141 and the auxiliary heating zones 1142, the temperatures of different parts of the sheet materials can be adjusted, thereby improving the problem of temperature differences at different parts of the sheet materials caused by asymmetric design of the sheet materials, the difference in distances between different parts of the sheet materials and the heater unit 40, the uneven heat resistance of different parts, etc., thereby facilitating the uniform distribution of temperature of the sheet materials and the uniform distribution of temperature in the furnace body 10, and further facilitating the processing quality of the sheet materials.

The cross section of the furnace tube 20 in a third direction is circular, but the cross section of the furnace tube 20 is not limited to circular, and may be substantially circular (such as elliptical), square, substantially square, etc. The third direction is a direction perpendicular to the length direction of the furnace tube 20. In addition, the furnace body 10 and the furnace tube 20 may be two parts connected to each other or two parts not connected to each other.

For better understanding, the processing equipment 100 and the control method thereof are further described below in conjunction with a first embodiment and a second embodiment. For the convenience of description, the first embodiment and the second embodiment are all shown with two main heating zones 1141 and two auxiliary heating zones 1142 as examples.

FIG. 4 illustrates a side view of the furnace body 10 and the furnace tube 20 of the processing equipment 100 of the first embodiment. As shown in FIG. 1, FIG. 2, and FIG. 4, the furnace chamber 11 of the furnace body 10 is divided into two main heating zones 1141 (i.e., A1 and A2), and two auxiliary heating zones 1142 (i.e., A3 and A4). The temperature sensor 30 is provided in the furnace tube 20, and the temperature sensor 30 is located in one of the main heating zones 1141. In some other embodiments, the temperature sensor 30 can be provided outside the furnace tube 20, for instance, the temperature sensor 30 can be arranged between the furnace body 10 and the furnace tube 20; or the temperature sensor 30 can be partially arranged in the furnace body 10. A specific arrangement position of the temperature sensor 30 is not limited by the present disclosure. FIG. 4 takes the temperature sensor 30 being arranged at the main heating zone A2 as an example. The temperature sensor 30 can be, for example, a thermocouple (for example, an S-type thermocouple, also known as a single platinum-rhodium thermocouple) or a temperature sensor 30 of other types, which is not specifically limited here. The actual temperature detected by the temperature sensor 30 is used as the actual temperature of the main heating zones A1 and A2.

When other temperature sensors 30 are provided between the furnace body 10 and the furnace tube 20, the temperature sensor 30 in the main heating zone 1141 and the temperature sensors 30 between the furnace body 10 and the furnace tube 20 are located in the same main heating zone 1141.

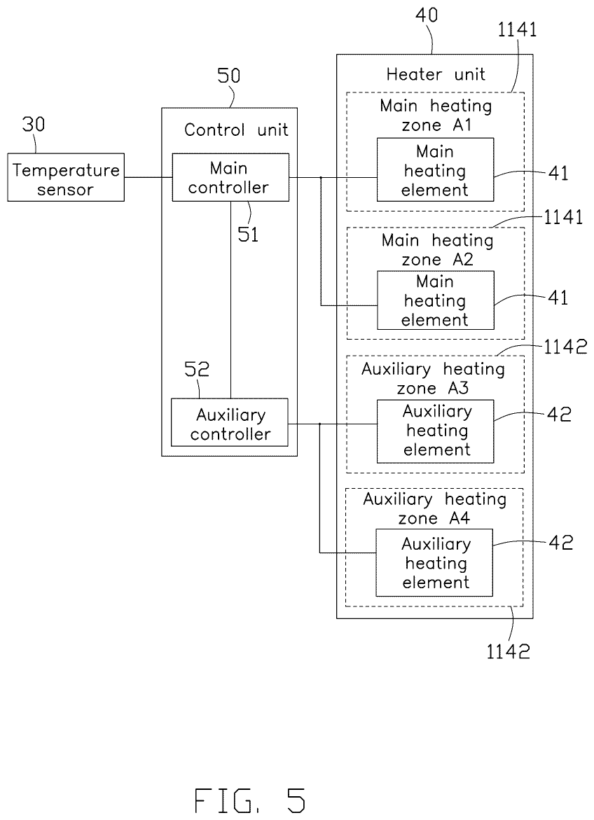

Referring to FIG. 5, the heater unit 40 includes two main heating elements 41 and two auxiliary heating elements 42, wherein one main heating element 41 is located in the main heating zone A1, and the other main heating element 41 is located in the main heating zone A2, one auxiliary heating element 42 is located in the auxiliary heating zone A3, and the other auxiliary heating element 42 is located in the auxiliary heating zone A4.

The control unit 50 includes a main controller 51 and an auxiliary controller 52, wherein the main controller 51 is connected to the temperature sensor 30 and the two main heating elements 41, and the auxiliary controller 52 is connected to the two auxiliary heating elements 42, and the auxiliary controller 52 is also coupled in series with the main controller 51. Based on this, the control unit 50 can jointly execute the control method of the processing equipment 100 provided in the first embodiment through the main controller 51 and the auxiliary controller 52 to achieve the temperature adjustment of the processing equipment 100.

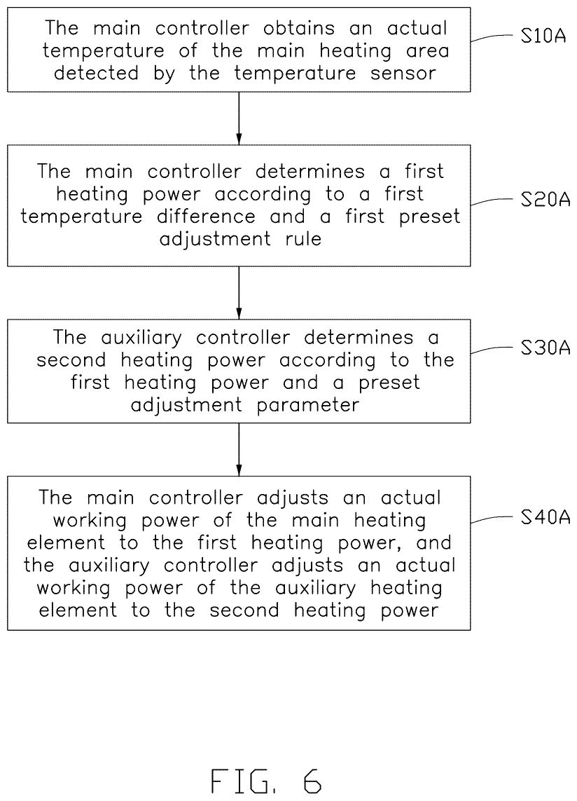

Specifically, referring to FIG. 6, the control method of the processing equipment 100 provided in the first embodiment includes the following steps S10A˜S40A. It should be noted that the temperature adjustment process of the processing equipment 100 generally includes a heating stage, a constant temperature stage, and a cooling stage, and the steps S10A˜S40A can be performed in the heating stage or the constant temperature stage.

In step S10A: the main controller 51 obtains an actual temperature of the main heating zone 1141 detected by the temperature sensor 30.

In step S20A: the main controller 51 determines a first heating power according to a first temperature difference and a first preset adjustment rule. The first temperature difference is a temperature difference between the actual temperature of the main heating zone 1141 and a preset target temperature. The first preset adjustment rule is used to indicate a corresponding relationship between a magnitude of the first temperature difference and the first heating power, and a corresponding relationship between a change rate of the first temperature difference and the first heating power.

That is, after obtaining the actual temperature of the main heating zone 1141, the actual temperature of the main heating zone 1141 can be subtracted from the target temperature to obtain the first temperature difference, and then the first preset adjustment rule is searched according to the first temperature difference to determine the first heating power corresponding to the first temperature difference.

At this time, the actual temperature of the main heating zone 1141 is usually lower than the target temperature, so the first temperature difference at this time is a negative value. Moreover, since the actual temperature detected by the temperature sensor 30 is not only the actual temperature of the main heating zone A2, but also the actual temperature of the main heating zone A1, therefore, the first heating power (or the first heating power of the main heating zone A2) corresponding to the first temperature difference between the main heating zone A2 and the target temperature is also the first heating power (or the first heating power of the main heating zone A1) corresponding to the first temperature difference between the actual temperature of the main heating zone A1 and the target temperature.

The target temperature can be set according to actual processing requirements and is not specifically limited here.

The first preset adjustment rule is associated with a magnitude of the first temperature difference and a change trend of the actual temperature of the main heating zone 1141. For instance, the first preset adjustment rule can be used to indicate that there is a positive correlation between the first temperature difference and the first heating power, and can also be used to indicate that within a preset temperature range, there is a negative correlation between the first change rate of the first temperature difference and the magnitude of the first heating power.

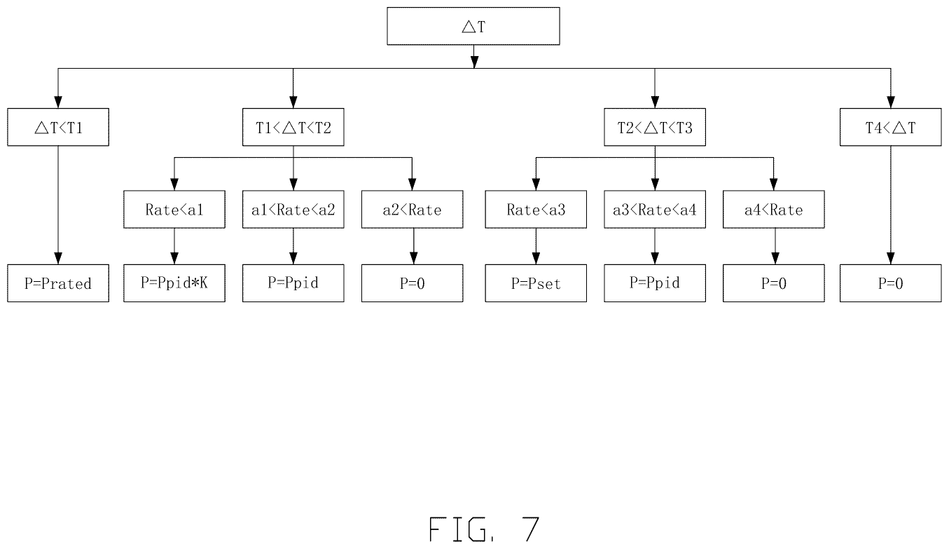

Exemplarily, as shown in FIG. 7, the first temperature difference is defined as ΔT, the first change rate is defined as Rate, the first heating power is defined as P, and the first preset adjustment rule may include:
When ΔT<T1, P=Prated.
When T1<ΔT<T2, and Rate<a1, P=Ppid*K.
When T1<ΔT<T2, and a1<Rate<a2, P=Ppid.
When T1<ΔT<T2, and a2<Rate, P=0.
When T2<ΔT<T3, and Rate<a3, P=Pset.
When T2<ΔT<T3, and a3<Rate<a4, P=Ppid.
When T2<ΔT<T3, and a4<Rate, P=0.
When T4<AT, P=0.

Prated is a rated working power of the main heating element 41. Ppid is a power obtained by PID adjustment. K is a preset multiple, K>1. Pset is a preset fixed power. The magnitudes of K and Pset can be set according to actual conditions, so that Prated>Ppid*K>Pset>Ppid>0.

T1 is a preset first temperature threshold. T2 is a preset second temperature threshold. T3 is a preset third temperature threshold. T4 is a preset fourth temperature threshold. The magnitudes of T1˜T4 can be set according to actual conditions, so that |T1|>|T2|>|T3|>|T4|. For example, T1 can be set to −50° C., T2 can be set to −30° C., T3 can be set to −10° C., and T4 can be set to 0.5° C. <T1, >T1 and <T2 (i.e., T1˜T2), >T2 and <T3 (i.e., T2˜T3), and >T4 are different temperature ranges.

a1 is a preset first rate threshold. a2 is a preset second rate threshold. a3 is a preset third rate threshold. a4 is a preset fourth rate threshold. The magnitudes of a1˜a4 can be set according to actual conditions, so that a2>a1, a4>a3. For example, a1 can be set to 0.2C°/s (degrees Celsius per second), a2 can be set to 0.3C°/s, a3 can be set to 0.05C°/s, and a4 can be set to 0.1C°/s.

It should be understood that the first preset adjustment rule described above is only an illustrative example provided in the first embodiment, and the first preset adjustment rule is not limited to this example. For example, in one case, Ppid*K may be equal to or less than Pset. Therefore, the first preset adjustment rule may be specifically designed according to actual conditions, and will not be listed one by one here.

In step S30A: the auxiliary controller 52 determines a second heating power according to the first heating power and a preset adjustment parameter. The preset adjustment parameter is used to indicate a magnitude relationship between the first heating power and the second heating power.

That is, after determining the first heating power, the first heating power can be subjected to corresponding mathematical operations according to the preset adjustment parameter to obtain the second heating power of the auxiliary heating zone 1142, and the magnitude relationship between the obtained second heating power and the first heating power is consistent with the magnitude relationship indicated by the preset adjustment parameter.

The preset adjustment parameter may be determined according to the actual situation. For example, the auxiliary controller 52 may be set according to the processing stage of the processing equipment 100, the processing time of the processing equipment 100, or the actual temperature of the first main heating zone 1141, so different preset adjustment parameters may be set in different situations.

In the first embodiment, the magnitude relationship between the preset adjustment parameter and the preset value is positively correlated with the magnitude relationship between the second heating power and the first heating power. For example, when the preset adjustment parameter is less than the preset value, the auxiliary controller 52 may determine that the second heating power is less than the first heating power. When the preset adjustment parameter is equal to the preset value, the auxiliary controller 52 may determine that the second heating power is equal to the first heating power. When the preset adjustment parameter is greater than the preset value, the auxiliary controller 52 may determine that the second heating power is greater than the first heating power.

A format of the preset adjustment parameter can be customized or defined by a preset rule, as long as the preset adjustment parameter can express its magnitude. For example, the preset adjustment parameter includes three Arabic numerals, such as the preset adjustment parameter m=500.

For further example, if the preset adjustment parameter m=500 and the preset value m0=100, since m>m0, a power value greater than the first heating power P1 is used as the second heating power P2. If the preset adjustment parameter m=100, the preset value m0=100, since m=m0, the power value of the first heating power P1 is used as the second heating power P2. If the preset adjustment parameter m=050 (that is, the magnitude of m is 50), the preset value m0=100, since m<m0, a power value less than the first heating power P1 is used as the second heating power P2.

In the first embodiment, the second heating power is positively correlated with the first heating power and the preset adjustment parameter. For example, the auxiliary controller 52 can multiply the first heating power, the preset adjustment parameter, and a preset ratio parameter to obtain the second heating power. When the first heating power is larger or the preset adjustment parameter is larger, the second heating power is also larger.

The preset ratio parameter may be a fixed value, and a magnitude of the preset ratio parameter is set according to actual conditions and is not limited here.

For further example, if the preset adjustment parameter m=500, the preset value m0=100, the preset ratio parameter n is 0.1, and the first heating power is P1, then the second heating power P2=n*m*P1=0.1*500*P1=50P1. If the preset adjustment parameter m=005 (that is, the magnitude of m is 5), the preset value m0=100, the preset ratio parameter n is 0.1, and the first heating power is P1, the second heating power

$$P 2 = n * m * P 1 = 0.1 * 5 * P 1 = 0.5 P 1 .$$

In addition, when there are a plurality of auxiliary heating zones 1142, the preset adjustment parameter can be used to indicate the magnitude relationship between the first heating power and the second heating powers of the plurality of auxiliary heating zones 1142. Specifically, in the first embodiment, the preset adjustment parameter include a first adjustment parameter and a second adjustment parameter. The first adjustment parameter can be used to indicate a magnitude relationship between the first heating power and the second heating power of the auxiliary heating zone A3, and the second adjustment parameter can be used to indicate a magnitude relationship between the first heating power and the second heating power of the auxiliary heating zone A4. The first adjustment parameter and the second adjustment parameter may be independent of each other or may be combined together, which is not specifically limited here.

For example, if the preset adjustment parameter m is formed by combining the first adjustment parameter and the second adjustment parameter, m=090020, wherein the first three digits (i.e., 090) are the first adjustment parameter, the last three digits (i.e., 020) are the second adjustment parameter, the preset ratio parameter n is 0.1, and the first heating power is P1, then the second heating power P2 of the auxiliary heating zone A3 is P2=n*m*P1=0.1*90*P1=9P1, and the second heating power P2 of the auxiliary heating zone A4 is P2-n*m*P1-0.1*20*P1-2P1. In other embodiments, alternatively, the first three digits of the preset adjustment parameter may be used as the second adjustment parameter, and the last three digits of the preset adjustment parameter may be used as the first adjustment parameter, that is, the second adjustment parameter is located before the first adjustment parameter.

The second heating power determined according to the first heating power and the preset adjustment parameter may be greater than a rated working power of the auxiliary heating element 42. Therefore, the control method may further include:

When the second heating power is greater than the rated working power of the auxiliary heating element 42, determining that the second heating power is equal to the rated working power of the auxiliary heating element 42.

Thus, the temperature of the auxiliary heating element 42 can be prevented from being too high, thereby preventing the materials or components in the auxiliary heating zone 1142 from being burned and affecting the processing effect.

In step S40A, the main controller 51 adjusts an actual working power of the main heating elements 41 to the first heating power, and the auxiliary controller 52 adjusts an actual working power of the auxiliary heating elements 42 to the second heating power.

In the step S40A, the main controller 51 can be connected to the main heating element 41 and the auxiliary heating element 42 through different power regulators. The main controller 51 can control the power regulators to adjust their output powers to the first heating power and then transmit same to the main heating element 41, and adjust their output powers to the second heating power and then transmit same to the auxiliary heating element 42. The power regulators can be integrated into the main controller 51 or can be independently set, which is not limited here.

When the actual working power of the main heating element 41 changes, the heat generation of the main heating element 41 also changes, thereby adjusting the actual temperature of the main heating zone 1141. The temperature adjustment process of the auxiliary heating element 42 on the auxiliary heating zone 1142 is similar, so it will not be repeated here.

During the sheet materials processing, the control unit 50 may perform the steps S10A to S40A multiple times to achieve real-time temperature control of each heating zone in the furnace body 10 and ensure that the temperature in the furnace body 10 is evenly distributed, so as to facilitate the sheet materials to form process layers.

When the process layers formed by the sheet materials meet the preset process requirements (for example, the thin film layer formed by the sheet materials through chemical vapor deposition reaches a preset thickness), it means that the sheet materials processing is completed, so the control unit 50 can stop executing the steps S10A to S40A. Therefore, the control method can also include:

When the process layer formed by the sheet material meets the preset process requirements, the main controller 51 adjusts the actual working power of the main heating element 41 to 0, and the auxiliary controller 52 adjusts the actual working power of the auxiliary heating element 42 to 0. In this way, the processing equipment 100 can be cooled down to facilitate subsequent operations.

In addition, during the cooling stage of the processing equipment 100, the control unit 50 also stops executing the steps S10A to S40A. Therefore, in this case, the main controller 51 adjusts the actual working power of the main heating element 41 to 0, and the auxiliary controller 52 adjusts the actual working power of the auxiliary heating element 42 to 0.

In general, the processing equipment 100 of the first embodiment divides the furnace body 10 into the main heating zones 1141 and the auxiliary heating zones 1142 which are distributed circumferentially, and sets the main heating element 41 in the main heating zones 1141 and the auxiliary heating element 42 in the auxiliary heating zones 1142. The control unit 50 uses the control method of the processing equipment 100 provided in the first embodiment to accurately control the operation of the main heating element 41 and the auxiliary heating element 42, thereby achieving temperature adjustment of the main heating zones 1141 and the auxiliary heating zones 1142, avoiding over-temperature or under-temperature, and ensuring that the temperature of the sheet materials and the temperature in the furnace body 10 can be evenly distributed.

In the control method of the first embodiment, the control unit 50 performs cascade control on the main heating element 41 and the auxiliary heating element 42, that is, the control unit 50 adjusts the working power of the main heating element 41 according to the actual temperature of the main heating zones 1141 to achieve the temperature adjustment of the main heating zones 1141, and adjusts the working power of the auxiliary heating element 42 according to the working power of the main heating element 41 to achieve the temperature adjustment of the auxiliary heating zones 1142. Therefore, the processing equipment 100 only needs to set the temperature sensor 30 in the main heating zones 1141, and does not need to set any other temperature sensors 30 in the auxiliary heating zones 1142. Therefore, the quantity of the temperature sensor 30 in the processing equipment 100 of the first embodiment can be small and the cost can be lower.

Further, the control unit 50 can adjust the working power of the main heating element 41 in stages or levels according to relevant temperature information (such as the magnitude and change rate of the first temperature difference) of the first temperature difference of the main heating zones 1141, thereby achieving precise temperature control of the main heating zones 1141. Since the working power of the auxiliary heating element 42 is based on the working power of the main heating element 41, the control unit 50 adjusts the working power of the auxiliary heating element 42 according to the working power of the main heating element 41, which can also achieve precise temperature control of the auxiliary heating zone 1142.

FIG. 8 illustrates a side view of the furnace body 10 and the furnace tube 20 of the processing equipment 100 of the second embodiment. As shown in FIGS. 1, 2, and 8, the furnace chamber 11 of the furnace body 10 is divided into two main heating zones 1141 (i.e., A1 and A2) and two auxiliary heating zones (i.e., A3 and A4).

The difference between the second embodiment and the first embodiment is that the second embodiment has a plurality of temperature sensors 30, which may include two main sensors 31 and two auxiliary sensors 32. One of the main sensors 31 is located in the main heating zone A1, another main sensor 31 is located in the main heating zone A2, one of the auxiliary sensors 32 is located in the auxiliary heating zone A3, and another auxiliary sensor 32 is located in the auxiliary heating zone A4. The temperature sensors 30 are used to detect the temperature of the main heating zones 1141 or the auxiliary heating zones 1142 where they are located.

The difference between the second embodiment and the first embodiment is that the connection relationship between the heater unit 40, the temperature sensors 30, and the control unit 50.

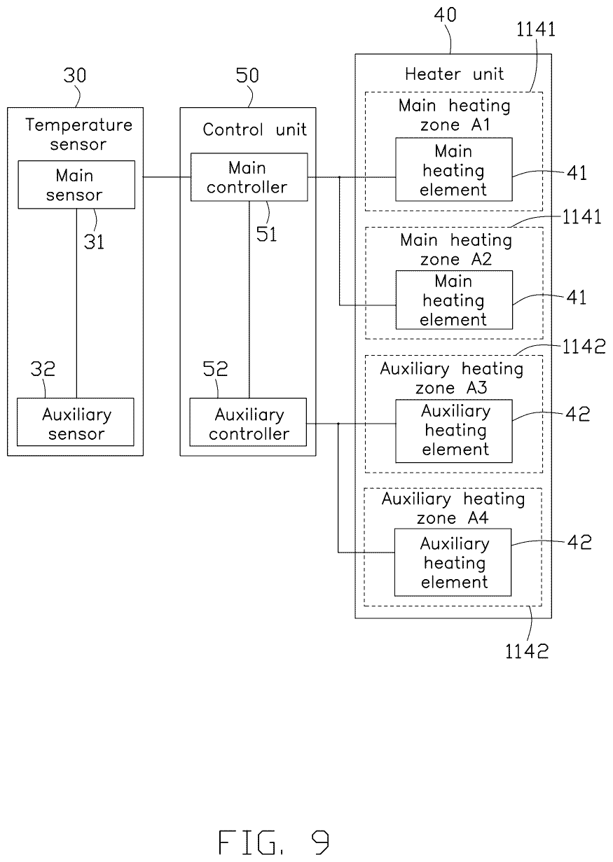

Specifically, referring to FIG. 9, the heater unit 40 of the second embodiment includes two main heating elements 41 and two auxiliary heating elements 42, and the control unit 50 includes a main controller 51 and an auxiliary controller 52. The main controller 51 is connected to the main sensor 31 and the two main heating elements 41, the auxiliary controller 52 is connected to the auxiliary sensor 32 and the two auxiliary heating elements 42. The auxiliary controller 52 is independent of the main controller 51 and is not cascade-coupled. Other descriptions of the heater unit 40, the temperature sensors 30, and the control unit 50 can be referred to in the first embodiment and will not be repeated here.

Based on such a structural design, the control method of the processing equipment 100 executed by the control unit 50 in the second embodiment is also different from the control method executed by the control unit 50 in the first embodiment.

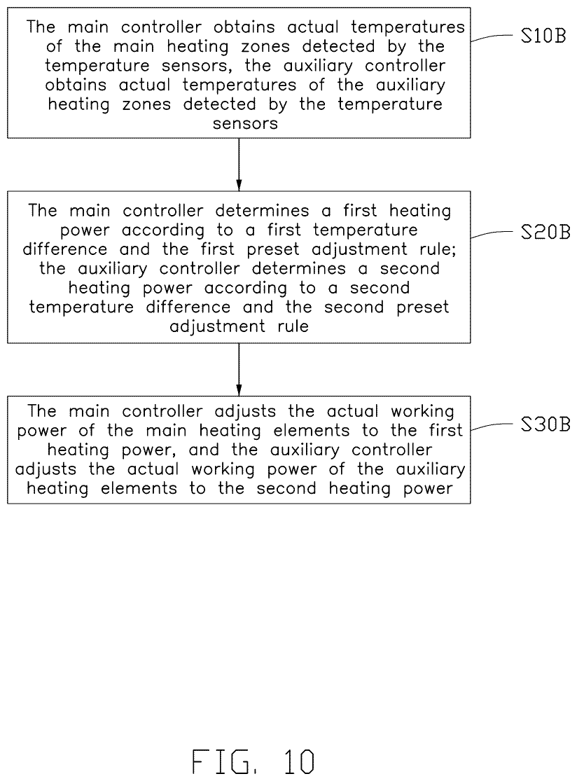

Specifically, referring to FIG. 10, the control method of the processing equipment 100 executed by the control unit 50 in the second embodiment includes the following steps:

In step S10B, the main controller 51 obtains actual temperatures of the main heating zones 1141 detected by the temperature sensors 30, the auxiliary controller 52 obtains actual temperatures of the auxiliary heating zones 1142 detected by the temperature sensors 30.

In step S20B, the main controller 51 determines a first heating power according to a first temperature difference and the preset target temperature and the first preset adjustment rule; the auxiliary controller 52 determines a second heating power according to a second temperature difference and the second preset adjustment rule.

The first temperature difference is a temperature difference between the actual temperature of the main heating zones 1141 and a preset target temperature. The second temperature difference is a temperature difference between the actual temperature of the auxiliary heating zones 1142 and the preset target temperature. The first preset adjustment rule is used to indicate the corresponding relationship between the magnitude of the first temperature difference and the first heating power, and the corresponding relationship between a change rate of the first temperature difference and the first heating power. The second preset adjustment rule is used to indicate a corresponding relationship between the magnitude of the second temperature difference and the second heating power, and a corresponding relationship between a change rate of the second temperature difference and the second heating power.

In step S30B, the main controller 51 adjusts the actual working power of the main heating elements 41 to the first heating power, and the auxiliary controller 52 adjusts the actual working power of the auxiliary heating elements 42 to the second heating power.

In the second embodiment, the first preset adjustment rule can be used to indicate that there is a positive correlation between the first temperature difference and the first heating power, and can also be used to indicate that within a preset temperature range, there is a negative correlation between the first change rate of the first temperature difference and the magnitude of the first heating power. For example, the first preset adjustment rule may be as shown in FIG. 7, for details, reference may be made to the relevant description of the first preset adjustment rule in the first embodiment, which will not be repeated here.

The second preset adjustment rule can be used to indicate that there is a positive correlation between the second temperature difference and the second heating power, and can also be used to indicate that within a preset temperature range, there is a negative correlation between the second change rate of the second temperature difference and the magnitude of the second heating power. For example, the second preset adjustment rule may be the same as or similar to the first preset adjustment rule, as shown in FIG. 7, where AT is the second temperature difference, Rate is the second change rate, P is the second heating power, and Prated is the rated operating power of the auxiliary heating element 42. Therefore, the second preset adjustment rule may refer to the relevant description of the first preset adjustment rule, which will not be repeated here.

It should be understood that the other contents of the processing equipment and the control method of the processing equipment of the second embodiment can also refer to the relevant description in the first embodiment, so they will not be repeated here.

In general, the processing equipment 100 of the second embodiment divides the furnace body 10 into the main heating zones 1141 and the auxiliary heating zones 1142 which are distributed circumferentially, sets the main heating elements 41 and the main sensor 31 in the main heating zones 1141, and sets the auxiliary heating elements 42 and the auxiliary sensor 32 in the auxiliary heating zones 1142. The control unit 50 uses the control method of the processing equipment 100 provided in the second embodiment to accurately control the operation of the main heating elements 41 and the auxiliary heating elements 42, thereby achieving temperature adjustment of the main heating zones 1141 and the auxiliary heating zones 1142 to avoid over-temperature or under-temperature, so that the temperature of the sheet materials and the temperature in the furnace body 10 can be evenly distributed.

In the control method of the second embodiment, the control unit 50 controls the main heating elements 41 and the auxiliary heating elements 42 independently, that is, the control unit 50 adjusts the working power of the main heating elements 41 according to the actual temperature of the main heating zones 1141 to achieve the temperature adjustment of the main heating zones 1141, and adjusts the working power of the auxiliary heating elements 42 according to the actual temperature of the auxiliary heating zones 1142 to achieve the temperature adjustment of the auxiliary heating zones 1142.

Furthermore, the control unit 50 can adjust the working power of the main heating elements 41 in stages or levels according to the relevant temperature information (such as the magnitude and change rate of the first temperature difference) of the first temperature difference of the main heating zones 1141, thereby achieving precise temperature control of the main heating zones 1141.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A control method of a processing equipment, the processing equipment comprising a furnace body, a furnace tube, a temperature sensor, and a heater unit, the heater unit arranged in the furnace body, the furnace body sleeved outside the furnace tube, the heater unit configured to generate heat when powered on, a furnace cavity of the furnace body divided into main heating zones and auxiliary heating zones along a circumference direction of the furnace body, the heater unit comprising main heating elements and auxiliary heating elements, the main heating elements located in the main heating zones correspondingly, the auxiliary heating elements located in the auxiliary heating zones correspondingly, the control method comprising:
obtaining an actual temperature detected by the temperature sensor;
determining a first heating power according to a first temperature difference and a first preset adjustment rule; wherein the first temperature difference is a temperature difference between the actual temperature of at least one of the main heating zones and a preset target temperature, the first preset adjustment rule is configured to indicate a corresponding relationship between a magnitude of the first temperature difference and the first heating power, and a corresponding relationship between a change rate of the first temperature difference and the first heating power;
determining a second heating power according to the first heating power and a preset adjustment parameter, wherein the preset adjustment parameter is configured to indicate a magnitude relationship between the first heating power and the second heating power; or determining the second heating power according to a second temperature difference and a second preset adjustment rule, wherein the second temperature difference is a temperature difference between the actual temperature of the auxiliary heating zones and the preset target temperature, the second preset adjustment rule is configured to indicate a corresponding relationship between a magnitude of the second temperature difference and the second heating power, and a corresponding relationship between a change rate of the second temperature difference and the second heating power;
adjusting an actual working power of the main heating elements to the first heating power, and adjusting an actual working power of the auxiliary heating elements to the second heating power.

2. The control method according to claim 1, wherein the first preset adjustment rule is configured to indicate there is a positive correlation between the first temperature difference and the first heating power; and/or, the first preset adjustment rule is configured to indicate that within a preset temperature range, there is a negative correlation between a first change rate of the first temperature difference and a magnitude of the first heating power;
the second preset adjustment rule is configured to indicate there is a positive correlation between the second temperature difference and the second heating power; and/or, the second preset adjustment rule is configured to indicate that within the preset temperature range, there is a negative correlation between a second change rate of the second temperature difference and a magnitude of the second heating power.

3. The control method according to claim 2, wherein the first preset adjustment rule is the same as the second preset adjustment rule, comprising:
when ΔT<T1, P=Prated;
when T1<ΔT<T2, and Rate<a1, P=Ppid*K;
when T1<ΔT<T2, and a1<Rate<a2, P=Ppid;
when T1<ΔT<T2, and a2<Rate, P=0;
when T2<ΔT<T3, and Rate<a3, P=Pset;
when T2<ΔT<T3, and a3<Rate<a4, P-Ppid;
when T2<ΔT<T3, and a4<Rate, P=0;
when T4<ΔT, P=0;
wherein P is the first heating power or the second heating power; Prated is a rated working power of the main heating elements or the auxiliary heating elements; Ppid is a power obtained by PID adjustment; K is a preset multiple, K>1; Pset is a preset fixed power; Prated>Ppid*K>Pset>Ppid>0;
ΔT is the first temperature difference or the second temperature difference; T1 is a preset first temperature threshold; T2 is a preset second temperature threshold; T3 is a preset third temperature threshold; T4 is a preset fourth temperature threshold; |T1|>|T2|>|T3|>|T4|;
Rate is the first change rate or the second change rate; a1 is a preset first rate threshold; a2 is a preset second rate threshold; a3 is a preset third rate threshold; a4 is a preset fourth rate threshold; a2>a1, a4>a3.

4. The control method according to claim 1, wherein the temperature sensor is arranged in the furnace tube, the heater unit is arranged between the furnace body and the furnace tube, determining the second heating power according to the first heating power and the preset adjustment parameter, comprises:
determining that the second heating power is less than the first heating power when the preset adjustment parameter is less than a preset value;
determining that the second heating power is equal to the first heating power when the preset adjustment parameter is equal to the preset value; and
determining that the second heating power is greater than the first heating power when the preset adjustment parameter is greater than the preset value.

5. The control method according to claim 1, wherein determining the second heating power according to the first heating power and the preset adjustment parameter, comprises:
multiplying the first heating power, the preset adjustment parameter, and a preset ratio parameter to obtain the second heating power.

6. The control method according to claim 5, further comprising:
determining that the second heating power is equal to a rated working power of the auxiliary heating elements when the second heating power is greater than the rated working power of the auxiliary heating elements.

7. A processing equipment comprising:
a furnace tube;
a furnace body sleeved outside the furnace tube, a furnace cavity of the furnace body divided into main heating zones and auxiliary heating zones along a circumference direction of the furnace body;
a temperature sensor;
a heater unit arranged in the furnace body, the heater unit configured to generate heat when powered on, the heater unit comprising main heating elements and auxiliary heating elements, the main heating elements located in the main heating zones correspondingly, the auxiliary heating elements located in the auxiliary heating zones correspondingly;
a control unit arranged outside the furnace body, the control unit connected to the temperature sensor and configured to obtain an actual temperature detected by the temperature sensor;
the control unit further connected to the main heating elements and the auxiliary heating elements, the control unit configured to determine a first heating power according to a first temperature difference and a first preset adjustment rule, determine a second heating power according to the first heating power and a preset adjustment parameter, adjust an actual working power of the main heating elements to the first heating power, and adjust an actual working power of the auxiliary heating elements to the second heating power;
wherein the first temperature difference is a temperature difference between the actual temperature of at least one of the main heating zones and a preset target temperature, the first preset adjustment rule is configured to indicate a corresponding relationship between a magnitude of the first temperature difference and the first heating power, the preset adjustment parameter is configured to indicate a magnitude relationship between the first heating power and the second heating power, and a corresponding relationship between a change rate of the first temperature difference and the first heating power.

8. The processing equipment according to claim 7, wherein the furnace cavity of the furnace body divided into N main heating zones and M auxiliary heating zones along the circumference direction of the furnace body, N and M are both positive integers not less than 2, N+M is an even number not less than 4, the N main heating zones are located in a first direction, the M auxiliary heating zones are located in a second direction, an angle between the first direction and a height direction of the furnace body is a right angle or an obtuse angle, and an angle between the second direction and the height direction of the furnace body is 0 or an acute angle.

9. The processing equipment according to claim 7, wherein the temperature sensor is arranged in the furnace tube, the heater unit is arranged between the furnace body and the furnace tube, the control unit comprises a main controller and an auxiliary controller, the main controller is connected to the temperature sensor and the main heating elements, the main controller is configured to obtain the actual temperature of the main heating zones detected by the temperature sensor, determine the first heating power according to the first temperature difference between the actual temperature of the main heating zones and the preset target temperature and the first preset adjustment rule, and adjust the actual working power of the main heating elements to the first heating power;
the auxiliary controller is coupled in series with the main controller, the auxiliary controller is connected to the auxiliary heating elements, the auxiliary controller is configured to determine the second heating power according to the first heating power and the preset adjustment parameter, and adjust the actual working power of the auxiliary heating elements to the second heating power.

10. The processing equipment according to claim 7, wherein a cross section of the furnace tube in a third direction is one of a circular, a substantial circular, a square, and a substantial square, the third direction is a direction perpendicular to a length direction of the furnace tube.

11. The processing equipment according to claim 7, wherein the first preset adjustment rule is configured to indicate there is a positive correlation between the first temperature difference and the first heating power; and/or, the first preset adjustment rule is configured to indicate that within a preset temperature range, there is a negative correlation between a first change rate of the first temperature difference and a magnitude of the first heating power;
the second preset adjustment rule is configured to indicate there is a positive correlation between the second temperature difference and the second heating power; and/or, the second preset adjustment rule is configured to indicate that within the preset temperature range, there is a negative correlation between a second change rate of the second temperature difference and a magnitude of the second heating power.

12. The processing equipment according to claim 11, wherein the first preset adjustment rule is the same as the second preset adjustment rule, comprising:
when ΔT<T1, P-Prated;
when T1<ΔT<T2, and Rate<a1, P=Ppid*K;
when T1<ΔT<T2, and a1<Rate<a2, P=Ppid;
when T1<ΔT<T2, and a2<Rate, P=0;
when T2<ΔT<T3, and Rate<a3, P=Pset;
when T2<ΔT<T3, and a3<Rate<a4, P=Ppid;
when T2<ΔT<T3, and a4<Rate, P=0;
when T4<AT, P=0;
wherein P is the first heating power or the second heating power; Prated is a rated working power of the main heating elements or the auxiliary heating elements; Ppid is a power obtained by PID adjustment; K is a preset multiple, K>1; Pset is a preset fixed power; Prated>Ppid*K>Pset>Ppid>0;
ΔT is the first temperature difference or the second temperature difference; T1 is a preset first temperature threshold; T2 is a preset second temperature threshold; T3 is a preset third temperature threshold; T4 is a preset fourth temperature threshold; |T1|>|T2|>|T3|>|T4|;
Rate is the first change rate or the second change rate; a1 is a preset first rate threshold; a2 is a preset second rate threshold; a3 is a preset third rate threshold; a4 is a preset fourth rate threshold; a2>a1, a4>a3.

13. The processing equipment according to claim 7, wherein the control unit configured to determine the second heating power according to the first heating power and the preset adjustment parameter, comprises:
determine that the second heating power is less than the first heating power when the preset adjustment parameter is less than a preset value;
determine that the second heating power is equal to the first heating power when the preset adjustment parameter is equal to the preset value; and
determine that the second heating power is greater than the first heating power when the preset adjustment parameter is greater than the preset value.

14. The processing equipment according to claim 7, wherein the control unit configured to determine the second heating power according to the first heating power and the preset adjustment parameter, comprises:
multiply the first heating power, the preset adjustment parameter, and a preset ratio parameter to obtain the second heating power.

15. The processing equipment according to claim 14, wherein the control unit is configured to determine that the second heating power is equal to a rated working power of the auxiliary heating elements when the second heating power is greater than the rated working power of the auxiliary heating elements.

16. A processing equipment comprising:
a furnace tube;
a furnace body sleeved outside the furnace tube, a furnace cavity of the furnace body divided into main heating zones and auxiliary heating zones along a circumference direction of the furnace body;
at least one temperature sensor;
a heater unit arranged in the furnace body, the heater unit configured to generate heat when powered on, the heater unit comprising main heating elements and auxiliary heating elements, the main heating elements located in the main heating zones correspondingly, the auxiliary heating elements located in the auxiliary heating zones correspondingly;
a control unit arranged outside the furnace body, the control unit connected to the at least one temperature sensor and configured to obtain an actual temperature detected by the at least one temperature sensor;
the control unit further connected to the main heating elements and the auxiliary heating elements, the control unit configured to determine a first heating power according to a first temperature difference and a first preset adjustment rule, determine a second heating power according to a second temperature difference and a second preset adjustment rule, adjust an actual working power of the main heating elements to the first heating power, and adjust an actual working power of the auxiliary heating elements to the second heating power;
wherein the first temperature difference is a temperature difference between the actual temperature of at least one of the main heating zones and a preset target temperature, the second temperature difference is a temperature difference between the actual temperature of the auxiliary heating zones and the preset target temperature, the first preset adjustment rule is configured to indicate a corresponding relationship between a magnitude of the first temperature difference and the first heating power, and a corresponding relationship between a change rate of the first temperature difference and the first heating power; the second preset adjustment rule is configured to indicate a corresponding relationship between a magnitude of the second temperature difference and the second heating power, and a corresponding relationship between a change rate of the second temperature difference and the second heating power.

17. The processing equipment according to claim 16, wherein the furnace cavity of the furnace body divided into N main heating zones and M auxiliary heating zones along the circumference direction of the furnace body, N and M are both positive integers not less than 2, N+M is an even number not less than 4, the N main heating zones are located in a first direction, the M auxiliary heating zones are located in a second direction, an angle between the first direction and a height direction of the furnace body is a right angle or an obtuse angle, and an angle between the second direction and the height direction of the furnace body is 0 or an acute angle.

18. The processing equipment according to claim 16, wherein the heater unit is arranged between the furnace body and the furnace tube, the at least one temperature sensor comprises main sensors and auxiliary sensors, the main sensors are arranged in the furnace tube and located in the main heating zones, the auxiliary sensors are arranged in the furnace tube and located in the auxiliary heating zones.

19. The processing equipment according to claim 18, wherein the control unit comprises a main controller and an auxiliary controller, the main controller is connected to the main sensors and the main heating elements, the main controller is configured to obtain the actual temperature of the main heating zones detected by the main sensors, determine the first heating power according to the first temperature difference between the actual temperature of the main heating zones and the preset target temperature and the first preset adjustment rule, and adjust the actual working power of the main heating elements to the first heating power;
the auxiliary controller is connected to the auxiliary sensors and the auxiliary heating elements, the auxiliary controller is configured to obtain the actual temperature of the auxiliary heating zones detected by the auxiliary sensors, determine the second heating power according to the second temperature difference between the actual temperature of the auxiliary heating zones and the preset target temperature and the second preset adjustment rule, and adjust the actual working power of the auxiliary heating elements to the second heating power.

20. The processing equipment according to claim 16, wherein a cross section of the furnace tube in a third direction is one of a circular, a substantial circular, a square, and a substantial square, the third direction is a direction perpendicular to a length direction of the furnace tube.
